(19) United States
(12) Patent Application Publication
(10) Pub. No.: US 2025/0291965 A1
(43) Pub. Date: Sep. 18, 2025

(54) METHOD AND SYSTEM FOR INTERACTING WITH COMPUTER-AIDED DESIGN MODELS

(71) Applicant: Siemens Industry Software Inc., Plano, TX (US)

(72) Inventors: Arthur S. Patrick, Madison, AL (US); Jeffrey Prozan, Huntsville, AL (US)

(21) Appl. No.: 18/602,853

(22) Filed: Mar. 12, 2024

(51) Int. Cl. G06F 30/17

(52) U.S. Cl. CPC G06F 30/17

(57) ABSTRACT

A computer-implemented method and system for interacting with a computer-aided design (CAD) model are described. A user selects one or more geometric entities in the CAD model. In response, the system identifies a first point associated with the one or more geometric entities and displays a repositionable graphical element in the user interface. In response to a second user input, the graphical element is displayed at a second point different from the first point, and the system dynamically displays a graphical representation of a relative position of the first point in relation to the second point in a predefined coordinate system.

### TECHNICAL FIELD

The present disclosure relates to methods for computer-aided design and manufacturing and, in particular, for interacting with computer-aided design models.

### BACKGROUND

Computer-Aided Design (CAD) systems are used in many fields of engineering, manufacturing, and design for solid modelling of objects. CAD systems provide a vast array of modelling and design tools to enable designers to modify models without having to reconfigure an entire design by hand. CAD systems may also integrate with other software tools, such as simulation software, product lifecycle management (PLM) systems, and computer-aided engineering (CAE) tools.

A user may interact with a model through a user interface provided by the CAD system. A user may select geometric structures via a user input device, such as a mouse, which may be represented on-screen by a visual aid or selection tool. Once an object is selected, the user may perform further operations on that object using the tools available through the interface.

Many real-world engineering scenarios such as placement of components within a mechanical assembly or alignment of structural elements in an architectural design require a high degree of precision and accuracy. In order to achieve this, CAD systems may provide functionality that enables the user to specify exact distances and relationships between objects. For example, some CAD systems enable users to define persistent dimensions or fixed reference points, which may be used to accurately measure distances. In other systems, a user may execute a move command and specify a “From Point” and “To Point” for an object.

The tools and techniques provided by existing CAD systems suffer from a number of shortcomings. In particular, these methods may be complex or unintuitive, requiring multiple interactions between the user and the system or foreknowledge of which commands to execute, or are limited by the geometric conditions that are supported by the system. There is therefore a need for providing improved interaction methods that allow a user to precisely position objects in a CAD system.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, a method that enables a user to modify geometric objects precisely and efficiently in a CAD model is provided.

The foregoing and other objects are achieved by the features of the independent claims. Further implementation forms are apparent from the dependent claims, the description and the figures.

According to a first aspect, a computer-implemented method for interacting with a computer-aided design (CAD) model in a user interface of a CAD system is provided. The method includes receiving a first user input via a user input device. The first user input includes a selection of one or more geometric entities in the CAD model. The method also includes, in response to the first user input: identifying a first point, O, associated with the one or more geometric entities; and displaying a repositionable graphical element in the user interface. The method includes displaying the graphical element at a second point, A, different from the first point, O, in a response to a second user input, and dynamically displaying a graphical representation of a relative position of the first point, O, in relation to the second point, A, in a predefined coordinate system.

The method according to the first aspect enables a user to position an anchor point and determine distances between the anchor point and geometric entities in a CAD model accurately and efficiently. The method is intuitive, efficient, and requires minimal user interaction.

In a first implementation form, the method includes receiving a third user input via the user input device. The third user input includes a modification of the relative position of the first point, O, in relation to the second point, A, in the predefined coordinate system. The method includes, in response to the third user input: modifying the position of the first point, O; and modifying at least the one or more geometric entities associated to the first point, O.

The first implementation form enables the accurate and efficient repositioning of geometric entities in a CAD model.

In a second implementation form, the method further includes dynamically updating the graphical representation of the relative position of the first point, O, in relation to the second point, A, in the predefined coordinate system, in response to the third user input.

The second implementation form provides the user with a visual indication of the updated position of an origin point and geometric entity in relation to an anchor point.

In a third implementation, in response to the first user input, the graphical element is displayed at a predetermined position in relation to the first point, O.

In a fourth implementation form, the method includes receiving a third user input, the third user input determining a third point, B, different from the first point, O, and second point, A. The method includes, in response to the third user input: repositioning the graphical element to the third point, B; and dynamically displaying a graphical representation of a position of the first point, O, in relation to the second point, B, in the predefined coordinate system.

The method according to the fourth implementation form allows the user to move the anchor point to a new position and to dynamically recalculate and display the positional data of the new anchor point in relation to the origin point.

In a fifth implementation form, the predefined coordinate system is a model space coordinate system, an auxiliary coordinate system, a user-defined coordinate system, or a combination of these.

In a sixth implementation form, the method includes displaying the relative position of the first point, O, in relation to the second point, A, in the predefined coordinate system as a persistent object in the CAD model.

In a seventh implementation form, the method includes receiving an instruction to swap the positions of the first point, O, and the second point, A. The method also includes, in response to the instruction: swapping the positions of the first point, O, and the second point, A; and repositioning the graphical element to the second point, A.

The method according to the seventh implementation form enables a user to change which object is being moved.

In an eighth implementation form, the method includes automatically identifying one or more geometric entities associated with the second point, A.

In a ninth implementation form, the method includes receiving an instruction to symmetrically transform the one or more geometric entities associated with the first point, O, and the one or more geometric entities associated with the second point; and symmetrically transforming the one or more geometric entities associated with the first point, O, and the one or more geometric entities associated with the second point, A.

In a tenth implementation form, the method includes receiving an instruction to rotate the one or more geometric entities associated with the first point, O, about the second point, A; and rotating the one or more geometric entities associated with the first point, O, about the second point, A, in response to the instruction.

In an eleventh implementation form, the method includes modifying the position of the first point, O, in relation to the second point, A, in the predefined coordinate system; and copying the at least the one or more geometric entities to the first point, O.

In a twelfth implementation form, the method includes receiving an instruction to reposition the first point, O to a third point, O′. The method also includes, in response to the instruction: repositioning the first point, O, to the third point O′; and dynamically displaying a graphical representation of a position of the third point, O′, in relation to the second point, A, in the predefined coordinate system.

These and other aspects of the invention will be apparent from the embodiments described below.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 shows a method for interacting with a computer-aided design (CAD) model, according to an example;

FIGS. 2A-2C show perspective illustrations of models of a component, according to an example;

FIG. 3A-3C show perspective illustrations of models of a pair of components, according to an example;

FIGS. 4A-4C show perspective illustrations of models of a component, according to an example;

FIG. 5 illustrates an example of a data processing system in which embodiments of the present disclosure may be implemented.

### DETAILED DESCRIPTION

Example embodiments are described below in sufficient detail to enable those of ordinary skill in the art to embody and implement the systems and processes herein described. It is important to understand that embodiments may be provided in many alternate forms and should not be construed as limited to the examples set forth herein.

Accordingly, while embodiments may be modified in various ways and take on various alternative forms, specific embodiments thereof are shown in the drawings and described in detail below as examples. There is no intent to limit to the particular forms disclosed. On the contrary, all modifications, equivalents, and alternatives falling within the scope of the appended claims should be included. Elements of the example embodiments are consistently denoted by the same reference numerals throughout the drawings and detailed description where appropriate.

The terminology used herein to describe embodiments is not intended to limit the scope. The articles “a,” “an,” and “the” are singular in that the articles have a single referent; however, the use of the singular form in the present document should not preclude the presence of more than one referent. In other words, elements referred to in the singular may number one or more, unless the context clearly indicates otherwise. It will be further understood that the terms “comprises,” “comprising,” “includes,” and/or “including,” when used herein, specify the presence of stated features, items, steps, operations, elements, and/or components, but do not preclude the presence or addition of one or more other features, items, steps, operations, elements, components, and/or groups thereof.

Unless otherwise defined, all terms including technical and scientific terms used herein are to be interpreted as is customary in the art. It will be further understood that terms in common usage should also be interpreted as is customary in the relevant art and not in an idealized or overly formal sense unless expressly so defined herein.

The methods described herein may be implemented in a computer-aided design (CAD), a computer aided manufacturing (CAM) system, a computer aided engineering (CAE) system, or similar. In CAD systems, a physical part is represented as an object with a description in terms of topological and geometric structures. Boundary representation (B-rep) technology dominates modem CAD modelling. B-reps provide an efficient and adaptable representation of parts by combining meshes and classic geometry: analytic surfaces and curves, non-uniform rational basis spline (NURBS), and procedural surfaces and curves.

The methods described herein simplify the process of measuring distances and modifying objects in two-dimensional and three-dimensional models. The user may drag a movable anchor point to any location in the model to measure and move selected objects. Dimensions are automatically shown between the anchor point and the objects to be moved or measured. These dimensions may be edited to precisely position the object. The methods allow precise and immediate positioning of selected objects relative to any easily selected points in the model. There is no need for a user to interact with the system to create persistent dimensions or relationships, or to perform extraneous measurements and mathematical computations.

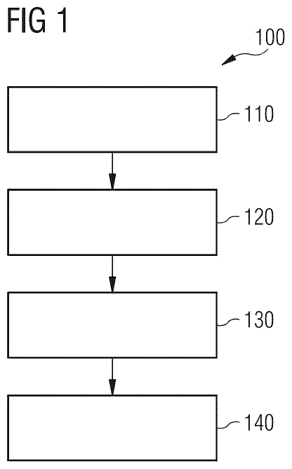

FIG. 1 is a block diagram of a computer-implemented method 100 for interacting with a computer-aided design (CAD) model in a user interface of a CAD system, according to an example. The method 100 may be used in conjunction with other methods and systems described herein.

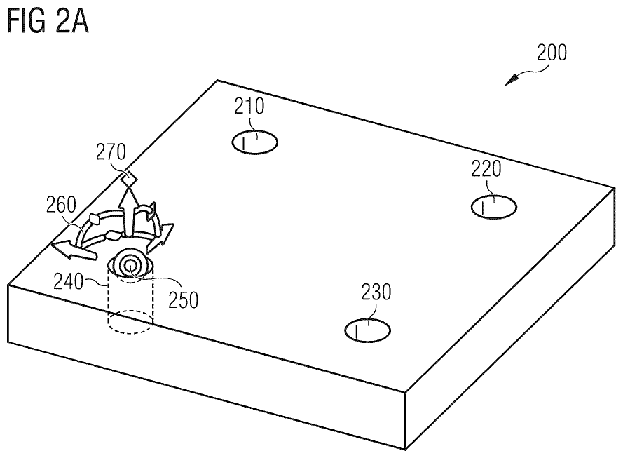

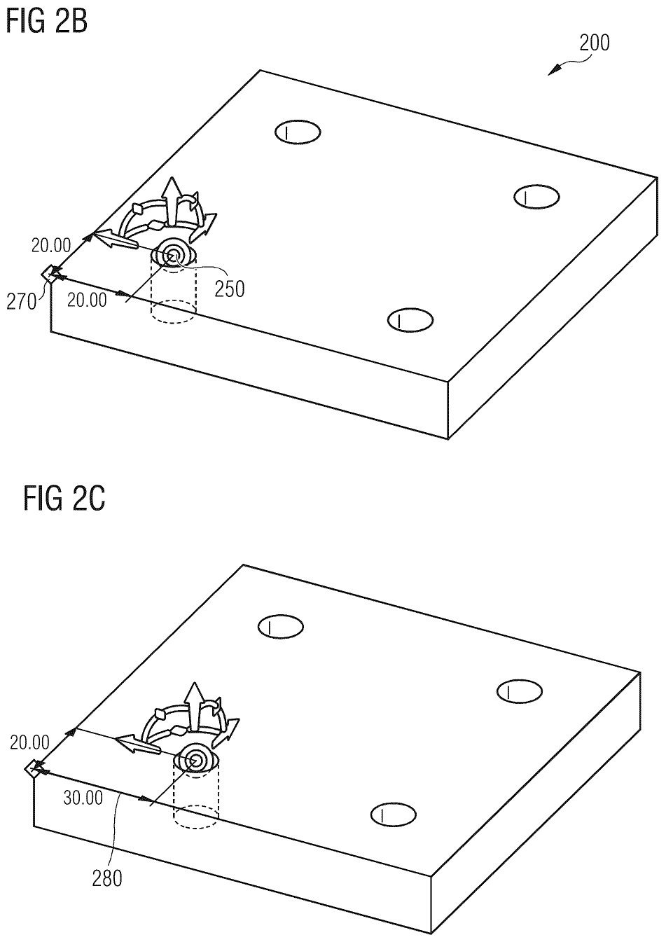

At block 110, the method 100 includes receiving a first user input via a user input device. According to examples described herein, the user input device may be a mouse, touchscreen, tablet, trackpad, or any other form of input device. The first user input includes a selection of one or more geometric entities in the CAD model. FIG. 2A shows an example of a CAD model 200, displayed in a user interface of a CAD system. The CAD model includes a square object, with holes 210, 220, 230, 240. Initially the user selects the hole 240, a geometric entity in the model 200.

At block 120, the method identifies a first point, O, associated with the one or more geometric entities, in response to the first user input. Referring again to FIG. 2A, when the user selects the hole 240, the CAD system automatically identifies the origin point 250, and a user selection tool 260 is displayed. The selection tool 260, which may also be referred to as a handle, includes a graphical representation of a set of axes. Various functions may be performed using the selection tool.

At block 130, the method 100 includes displaying a repositionable graphical element in the user interface. Referring to FIG. 2A, the CAD system displays a repositionable graphical element 270. The repositionable graphical element 270, which is also referred to herein as an anchor point, may initially be positioned above the selection tool 260. In general, when a planar face of an object is selected, an anchor point may appear automatically at the nearest perpendicular point through the model. When a cylindrical face is selected, an anchor point may appear at near the identified origin point, O.

At block 140, the method 100 includes displaying the repositionable graphical element at a second point, A, different from the first point, O, in response to a second user input. The user input may be provided by a click of a mouse button that selects the second point, or by selecting the anchor point 270 and dragging and dropping the anchor point 270 to the desired position. Referring to FIG. 2B, the user provides input that moves the anchor point 270 to a second position at the corner of the object 200, which is different than the position of the origin point 250. In the example shown in FIG. 2B, the second position is a point on the geometry of the model 200. In other examples, the second point may be a point in space.

At block 150, the method 100 includes dynamically displaying a graphical representation of a relative position of the first point, O, in relation to the second point, A, in a predefined coordinate system. The graphical representation of the position is displayed automatically and instantaneously as soon as the user moves the anchor point to the second point, A, without any user input. Referring again to FIG. 2B, in response to the user moving the anchor point 270 to the corner of the model 200, the CAD system dynamically displays relative distances (20.00, 20.00, 0) between the anchor point 270 and the origin 250. The distances are measurements along three primary measurement axes in the model space of the model 200. In other examples, the distances may be relative to other three-dimensional coordinate systems such as the coordinate system of the selection tool, a user defined coordinate system, an auxiliary coordinate system, or system-implied measurement directions.

The method 100 enables a user to determine an exact relative position of a selected geometric entity in a model with respect to an anchor point in a single click. The user may modify the position of the selected geometric entity by modifying the relative position of the origin point with respect to the position of the anchor point. The user interface in the CAD system may display the distances in a display window, in an editable format allowing the user to edit the values. Referring to FIG. 2C, the distances (20.00, 20.00, 0) have been modified to (30.00, 20.00, 0). This moves the origin point 250 and the associated geometric entity (e.g., hole 240) by a distance 10.00 in the x-axis direction 280 of the model space. There is no need for the user to create persistent dimensions in the model in order to modify the position of the hole 240: the relative distances are displayed dynamically, and the hole 240 is repositioned automatically when the user modifies the relative distances. If the user wishes to create persistent dimensions, then the temporary distances may be converted into persistent dimensions.

The user may subsequently reposition the anchor point or the origin point, and the graphical representation of the relative distances between the points dynamically updates to reflect the new relative position of the points. Subsequently, the user may choose to perform further modifications by modifying values between the anchor point and origin points to modify geometry. The process of selecting an anchor point, modifying geometry, and subsequently repositioning the anchor and/or origin points may be continued indefinitely by a user. Sequences of precise modifications to the model geometry may be achieved with far fewer rounds of interaction than prior systems.

In some cases, the user may also swap the origin point and the anchor point to change which object is moved by a subsequent modification of the relative position between the anchor point and origin point. In other examples, the method enables a user to symmetrically move objects such that both objects are moved in opposing directions by equal distances. In further examples, the method enables the user to copy selected objects to the new location rather than transforming the original object. In further examples, angular dimensions may be used to rotate objects about an anchor point rather than transforming objects.

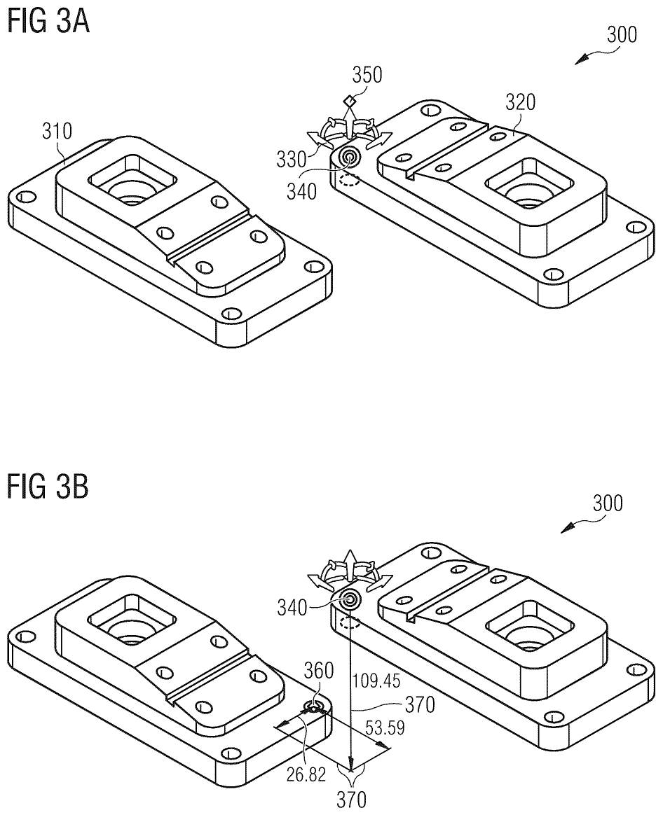

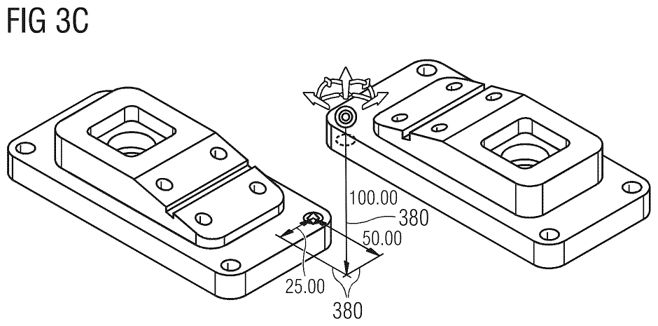

The methods described herein may be used to reposition one component relative to another, separate component. FIG. 3A shows a second example of a CAD model 300, displayed in a user interface of a CAD system. The model 300 includes objects 310, 320, that may represent physical components for manufacture.

In FIG. 3A, the user selects the object 320 using a selection tool 330. The system identifies an origin point 340 based on the selection of the user, and a repositionable anchor point 350 appears above the selection tool 330. FIG. 3B shows the same model as FIG. 3A. In FIG. 3B, the user has repositioned the anchor point 350 to a new position 360. The system dynamically displays the relative distances 370 between the origin point 340 and the anchor point 350 at the new position 360 in the model space coordinate system.

FIG. 3C shows the same model 300 as FIGS. 3A and 3B. In FIG. 3C, the user has modified the values (53.59, 26.82, 109.45) for the relative distances between the origin and anchor to a new set 380 of values (50.00, 25.00, 100.00). This results in the object 320 moving towards the object 310.

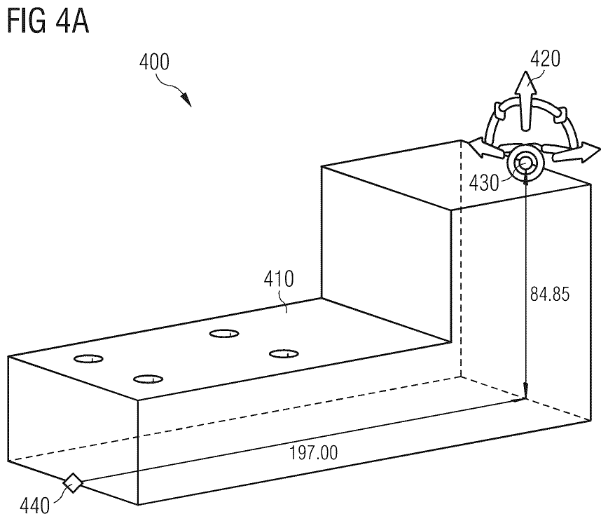

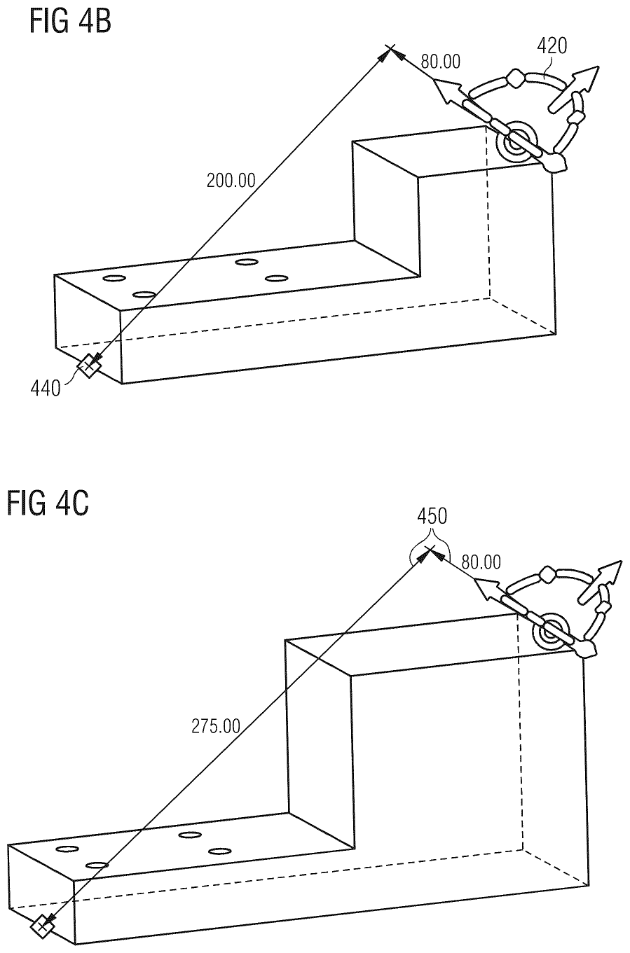

FIG. 4A shows a third example of a CAD model 400 displayed in a user interface of a CAD system. The model 400 includes an object 410. In FIG. 4A, the user selects a position on an edge of a face of the object 410 using selection tool 420, and the system identifies origin point 430. A repositionable anchor point 440 appears on an edge of an opposing face of the object 410. FIG. 4B shows the same model 400 as FIG. 4A. In FIG. 4B, the user has rotated the axes of the selection tool 420. The system dynamically recalculates and displays relative distances between the origin point 430 and the anchor point 440 with respect to the rotated axes of the selection tool 420.

FIG. 4C shows the same model 400 as FIGS. 4A and 4B. In FIG. 4C, the user has modified the values (200.00, 80.00) for the relative distances between the origin and anchor to a new set of values 450 equal to (275.00, 80.00). This results in a heightening and lengthening of the object.

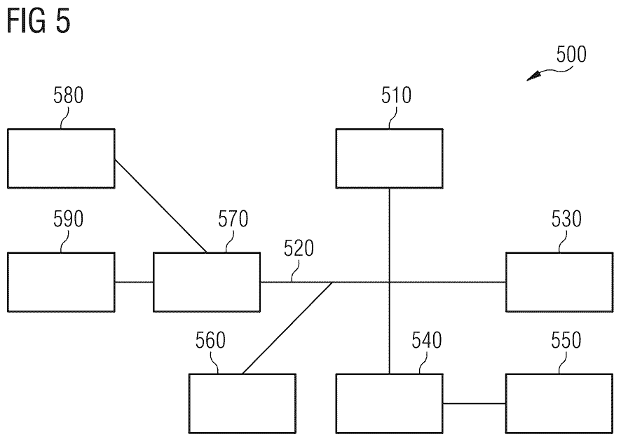

FIG. 5 illustrates an example of a data processing system in which an embodiment of the present disclosure may be implemented (e.g., a CAD application configured to perform the methods of the embodiments of the present invention as described herein). The data processing system 500 includes a processor 510 connected to a local system bus 520. The local system bus connects the processor to a main memory 530 and graphics display adaptor 540, which may be connected to a display 550. The data processing system may communicate with other systems via a wireless user interface adapter connected to the local system bus 520, or via a wired network, for example, to a local area network. Additional memory 560 may also be connected via the local system bus 520.

A suitable adaptor, such as wireless user interface adapter 570, for other peripheral devices, such as a keyboard 580 and mouse 590, or other pointing device, allows the user to provide input to the data processing system. Other peripheral devices may include one or more I/O controllers such as USB controllers, Bluetooth controllers, and/or dedicated audio controllers (e.g., connected to speakers and/or microphones). It should also be appreciated that various peripherals may be connected to the USB controller (e.g., via various USB ports) including input devices (e.g., keyboard, mouse, touch screen, trackball, camera, microphone, scanners), output devices (e.g., printers, speakers), or any other type of device that is operative to provide inputs or receive outputs from the data processing system.

Further, it should be appreciated that many devices referred to as input devices or output devices may both provide inputs and receive outputs of communications with the data processing system. Further, it should be appreciated that other peripheral hardware connected to the I/O controllers may include any type of device, machine, or component that is configured to communicate with a data processing system.

An operating system included in the data processing system enables an output from the system to be displayed to the user on the display and the user to interact with the system. Examples of operating systems that may be used in a data processing system may include Microsoft Windows™, Linux™, UNIX™, iOS™, and Android™ operating systems.

In addition, it should be appreciated that data processing system 500 may be implemented as in a networked environment, distributed system environment, virtual machines in a virtual machine architecture, and/or cloud environment. For example, the processor and associated components may correspond to a virtual machine executing in a virtual machine environment of one or more servers.

Those of ordinary skill in the art will appreciate that the hardware depicted for the data processing system 500 may vary for particular implementations. For example, the data processing system 500 in this example may correspond to a computer, workstation, and/or a server. However, it should be appreciated that alternative embodiments of a data processing system may be configured with corresponding or alternative components such as in the form of a mobile phone, tablet, controller board, or any other system that is operative to process data and carry out functionality and features described herein associated with the operation of a data processing system, computer, processor, and/or a controller discussed herein. The depicted example is provided for the purpose of explanation only and is not meant to imply architectural limitations with respect to the present disclosure.

The data processing system 500 may be connected to the network (e.g., not a part of data processing system 500), which may be any public or private data processing system network or combination of networks, as known to those of skill in the art, including the Internet. The data processing system 500 may communicate over the network with one or more other data processing systems such as a server (e.g., also not part of the data processing system 500). However, an alternative data processing system may correspond to a plurality of data processing systems implemented as part of a distributed system in which processors associated with a number of (e.g., several) data processing systems may be in communication via one or more network connections and may collectively perform tasks described as being performed by a single data processing system. Thus, it is to be understood that when referring to a data processing system, such a system may be implemented across a number of (e.g., several) data processing systems organized in a distributed system in communication with each other via a network.

The data processing system 500 is adapted to carry out the methods in accordance with the embodiments described herein. For example, the keyboard 580 and mouse 590 may function as a user input device for receiving information from the user, the processor 510 may be adapted to carry out the steps of the method, and the display 550 may be adapted to display a particular view to the user. A computer product including instructions that, when run on a computer, such as the data processing system 500, cause the computer to execute the steps of the methods of the embodiments of the present invention outlined above may be provided.

The present disclosure is described with reference to flow charts and/or block diagrams of the method, devices, and systems according to examples of the present disclosure. Although the flow diagrams described above show a specific order of execution, the order of execution may differ from that which is depicted. Blocks described in relation to one flow chart may be combined with those of another flow chart. In some examples, some blocks of the flow diagrams may not be necessary and/or additional blocks may be added.

The present inventions may be embodied in other specific apparatus and/or methods. The described embodiments are to be considered in all respects as illustrative and not restrictive. In particular, the scope of the invention is indicated by the appended claims rather than by the description and figures herein. All changes that come within the meaning and range of equivalency of the claims are to be embraced within their scope.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A method for interacting with a computer-aided design (CAD) model in a user interface of a CAD system, the method being computer-implemented and comprising:
receiving a first user input via a user input device, the first user input comprising a selection of one or more geometric entities in the CAD model;
in response to the first user input:
identifying a first point, O, associated with the one or more geometric entities; and
displaying a repositionable graphical element in the user interface;
displaying the repositionable graphical element at a second point, A, different from the first point, O, in a response to a second user input; and
dynamically displaying a graphical representation of a relative position of the first point, O, in relation to the second point, A, in a predefined coordinate system.

2. The method of claim 1, further comprising:
receiving a third user input via the user input device, the third user input comprising a modification of the relative position of the first point, O, in relation to the second point, A, in the predefined coordinate system; and
in response to the third user input:
modifying a position of the first point, O; and
modifying at least the one or more geometric entities associated with the first point, O.

3. The method of claim 2, further comprising dynamically updating the graphical representation of the relative position of the first point, O, in relation to the second point, A, in the predefined coordinate system, in response to the third user input.

4. The method of claim 1, wherein, in response to the first user input, the repositionable graphical element is displayed at a predetermined position in relation to the first point, O.

5. The method of claim 1, further comprising:
receiving a third user input, the third user input determining a third point, B, different from the first point, O, and the second point, A; and
in response to the third user input:
repositioning the repositionable graphical element to the third point, B; and
dynamically displaying a graphical representation of a position of the first point, O, in relation to the second point, B, in the predefined coordinate system.

6. The method of claim 1, wherein the predefined coordinate system is a model space coordinate system, an auxiliary coordinate system, a user-defined coordinate system, or a combination thereof.

7. The method of claim 1, further comprising:
displaying the relative position of the first point, O, in relation to the second point, A, in the predefined coordinate system as a persistent object in the CAD model.

8. The method of claim 1, further comprising:
receiving an instruction to swap positions of the first point, O, and the second point, A; and
in response to the instruction:
swapping the positions of the first point, O, and the second point, A;
repositioning the graphical element to the second point, A; and
dynamically updating the graphical representation of the position of the first point, O, in relation to the second point, A, in the predefined coordinate system.

9. The method of claim 1, further comprising, in response to the second user input:
automatically identifying one or more geometric entities associated with the second point, A.

10. The method of claim 9, further comprising:
receiving an instruction to symmetrically transform the one or more geometric entities associated with the first point, O, and the one or more geometric entities associated with the second point, A; and
symmetrically transforming the one or more geometric entities associated with the first point, O, and the one or more geometric entities associated with the second point, A.

11. The method of claim 1, further comprising:
receiving an instruction to rotate the one or more geometric entities associated with the first point, O, about the second point, A; and
rotating the one or more geometric entities associated with the first point, O, about the second point, A, in response to the instruction.

12. The method of claim 1, further comprising:
modifying the position of the first point, O, in relation to the second point, A, in the predefined coordinate system; and
copying the at least the one or more geometric entities to the first point, O.

13. The method of claim 1, further comprising:
receiving an instruction to reposition the first point, O to a third point, O′; and
in response to the instruction:
repositioning the first point, O, to the third point O′; and
dynamically displaying a graphical representation of a position of the third point, O′, in relation to the second point, A, in the predefined coordinate system.

14. A computer program product comprising a non-transitory computer-readable storage medium that stores instructions executable by a computer for interacting with a computer-aided design (CAD) model in a user interface of a CAD system, the instructions comprising:
receiving a first user input via a user input device, the first user input comprising a selection of one or more geometric entities in the CAD model;
in response to the first user input:
identifying a first point, O, associated with the one or more geometric entities; and
displaying a repositionable graphical element in the user interface;
displaying the repositionable graphical element at a second point, A, different from the first point, O, in a response to a second user input; and
dynamically displaying a graphical representation of a relative position of the first point, O, in relation to the second point, A, in a predefined coordinate system.

15. A data processing system comprising:
a processor and a memory storing instructions that, when implemented by the processor, cause the processor to:
interact with a computer-aided design (CAD) model in a user interface of a CAD system, the interaction comprising:
receipt of a first user input via a user input device, the first user input comprising a selection of one or more geometric entities in the CAD model;
in response to the first user input:
identification of a first point, O, associated with the one or more geometric entities; and
display of a repositionable graphical element in the user interface;
display of the repositionable graphical element at a second point, A, different from the first point, O, in a response to a second user input; and
dynamic display of a graphical representation of a relative position of the first point, O, in relation to the second point, A, in a predefined coordinate system.
